(19) United States
(12) Patent Application Publication
(10) Pub. No.: US 2009/0261816 A1
(43) Pub. Date: Oct. 22, 2009

(54) NIGHT-GLOW INDICATOR SYSTEM

(76) Inventor: Henry Hyunbo Shim, Los Angeles, CA (US)

Correspondence Address: PARK LAW FIRM, 3255 WILSHIRE BLVD, SUITE 1110, LOS ANGELES, CA, 90010, US

(21) Appl. No.: 12/104,651

(22) Filed: Apr. 17, 2008

(51) Int. Cl. G01R 11/00

(52) U.S. Cl. 324/157

(57) ABSTRACT

A night-glow color coded device system is provided. The system comprises an operational device, a case, first night-glow patches, second night-glow patches, and color codes. The case encloses and supports operational parts. The first night-glow patches are attached on at least one of the operational parts. The second night-glow patches are attached on the case in a vicinity of the operational parts, and the second night-glow patches indicates information on the operational parts. The color codes are provided on the case, and indicates at least one of the information. The first night-glow patches glow in a fluorescent light different from the second night-glow patches, and the information comprises operational status including ON and OFF of the operational device.

### BACKGROUND OF THE INVENTION

The present invention relates to an night-glow indicator system. More particularly, this invention relates to an night-glow indicator system which makes parts of a device or information on the device glow in the dark.

Due to the fact that human can see light of a particular frequency range, darkness and therefore night has overshadowed human activities and limited the temporal and spatial ranges thereof.

Frequently, darkness was identified as source of evil or at least trouble. Actually, since the amount of information received with eyes consists of such a large portion, in the dark where eyes go useless, people get easily caught in trouble.

The night-glow indicator system is able to help the people in the dark in many situation.

Accordingly, a need for night-glow indicator system has been present for a long time considering the wide range of potential application. This invention is directed to satisfy the long-felt need.

### SUMMARY OF THE INVENTION

An objective of the invention is to provide an night-glow indicator system.

Another object of the invention is to provide night-glow indicator system, which can help people in using electrical devices.

Still another object of the invention is to provide a night-glow indicator system, which can help people in using mechanical device.

An aspect of the invention provides an night-glow indicator system provides a night-glow power outlet.

The night-glow power outlet has one or more power outlet openings, comprising a case and one or more night-glow patches.

The case is configured for enclosing and supporting the one or more power outlet openings.

The one or more night-glow patches are attached on the case in a vicinity of the one or more power outlet openings, and the one or more night-glow patches are configured to indicate information on the one or more power outlet openings.

The information comprises rms voltage, peak voltage, rms current, maximum current, and frequency of power, wherein the information further comprises positions of the one or more power outlet openings. Some of the one or more night-glow patches are disposed around the one or more power outlet openings, and the one or more night-glow patches are arranged to form patterns for indicating the information in the dark.

The one of the night-glow patches may comprise a hole that has a same shape and size of one of the power outlet openings, and the night-glow patch may be disposed on the power outlet opening with the hole overlapped on the power outlet opening.

Some of the one or more night-glow patches may be disposed along edges of the case.

The patterns may comprise bar-codes, alphanumeric characters, warning symbols, and geometrical shapes.

The night-glow power outlet may further comprise one or more color codes, and the one or more color codes may be configured to indicate the information.

The one or more night-glow patches may comprise the one or more color codes such that the one or more night-glow patches glow in the dark and display colors in the light.

Another aspect of the invention provides a night-glow power cord having an electrical cord and two or more prongs provided at an end of the electrical cord.

The night-glow power cord comprises a case and one or more night-glow patches.

The case is provided between the prongs and the electrical cord and configured for enclosing and supporting the two or more prongs.

The one or more night-glow patches are attached on the case in a vicinity of the two or more prongs, and the one or more night-glow patches are configured to indicate information on the two or more prongs and an electrical device connected to the electrical cord.

The information comprises rms voltage, peak voltage, rms current, maximum current, and frequency of power, and the information further comprises positions of the prongs. Some of the one or more night-glow patches are disposed around the two or more prongs, and the one or more night-glow patches are arranged to form patterns for indicating the information in the dark. Some of the one or more night-glow patches may be disposed along edges of the case. The patterns may comprise bar-codes, alphanumeric characters, warning symbols, and geometrical shapes.

The night-glow power cord may further comprise one or more color codes, and the one or more color codes may be configured to indicate the information.

The one or more night-glow patches may comprise the one or more color codes such that the one or more night-glow patches glow in the dark and display colors in the light.

Still another aspect of the invention provides a night-glow color coded device system.

The night-glow color coded device system comprises an operational device, a case, a plurality of first night-glow patches, a plurality of second night-glow patches, and a plurality of color codes.

The operational device comprises a plurality of operational parts.

The case is configured for enclosing and supporting the plurality of operational parts.

The plurality of first night-glow patches are attached on at least one of the operational parts.

The plurality of second night-glow patches are attached on the case in a vicinity of the operational parts, and the second night-glow patches are configured to indicate information on the operational parts.

The plurality of color codes are provided on the case, and the color codes are configured to indicate at least one of the information.

The first night-glow patches glow in a fluorescent light different from the second night-glow patches, and the information comprises operational status including ON and OFF of the operational device. The one or more night-glow patches are arranged to form patterns for indicating the information in the dark.

The operational device may comprise an electrical device, and the operational parts may comprise power switches, control buttons, and connectors.

The operational device may comprise a mechanical device, and the operational parts may comprise handles, access points, maintenance guide lines, windows, and doors.

The one or more night-glow patches may comprise some of the color codes such that the one or more night-glow patches glow in the dark and display colors in the light.

The operational device may comprise an automobile, and the operational parts may comprise handles, knobs, indicators, and output ports of an automobile.

The operational device may comprise a fire extinguisher, and the operational parts may comprise hose, hose connectors, release pins, handles, holders, and direction plates.

The operational device may comprise a container configured to contain chemical or medical contents, and the operational parts may comprise a lid and an outer surface.

The first night-glow patches may be substantially same as the second night-glow patches, and the night-glow patches may be applied all over the operational device.

Since the invention relates to night-glow indicator systems, the operational device may comprises many devices, a part or an entire body of which needs to be seen in the dark. Such devices may comprise switches, buttons, controls, handles, connectors, docking ports, indicators, containers, knobs, warning signs, instruction plates, etc.

The advantages of the present invention are: (1) the night-glow indicator system helps people using a plurality of devices in the dark; and (2) the night-glow indicator system provides a lot of information to users so that misusing is prevented.

Although the present invention is briefly summarized, the fuller understanding of the invention can be obtained by the following drawings, detailed description and appended claims.

### BRIEF DESCRIPTION OF THE DRAWINGS

These and other features, aspects and advantages of the present invention will become better understood with reference to the accompanying drawings, wherein:

FIG. 1 is a perspective view of an night-glow power outlet according to an embodiment of the invention;

FIG. 2 is a partial perspective view of the night-glow power outlet of FIG. 1;

FIG. 3 is a perspective view of a power extension with night-glow indicator system with night-glow indicator system according to another embodiment of the invention;

FIG. 4 is a perspective view of a mechanical device with night-glow indicator system according to still another embodiment of the invention;

FIG. 5 is a top plan view of a switch set with night-glow indicator system according an embodiment of the invention;

FIG. 6 is a top plan view of a switch with night-glow indicator system according another embodiment of the invention;

FIG. 7 is a side plan view of a flashlight with night-glow indicator system according still another embodiment of the invention;

FIG. 8 is a front plan view of a meter with night-glow indicator system according still another embodiment of the invention; and

FIG. 9 is a front plan view of a door with night-glow indicator system according an embodiment of the invention.

### DETAILED DESCRIPTION EMBODIMENTS OF THE INVENTION

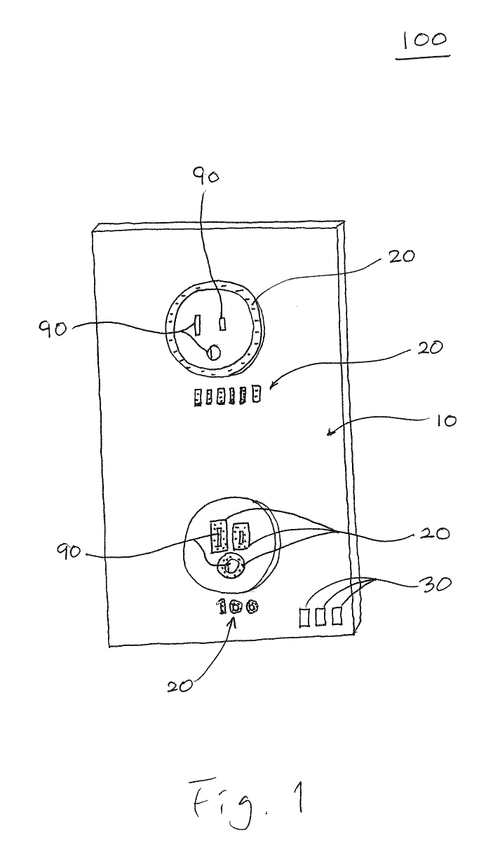

FIGS. 1-4 show night-glow indicator systems according to embodiments of the invention.

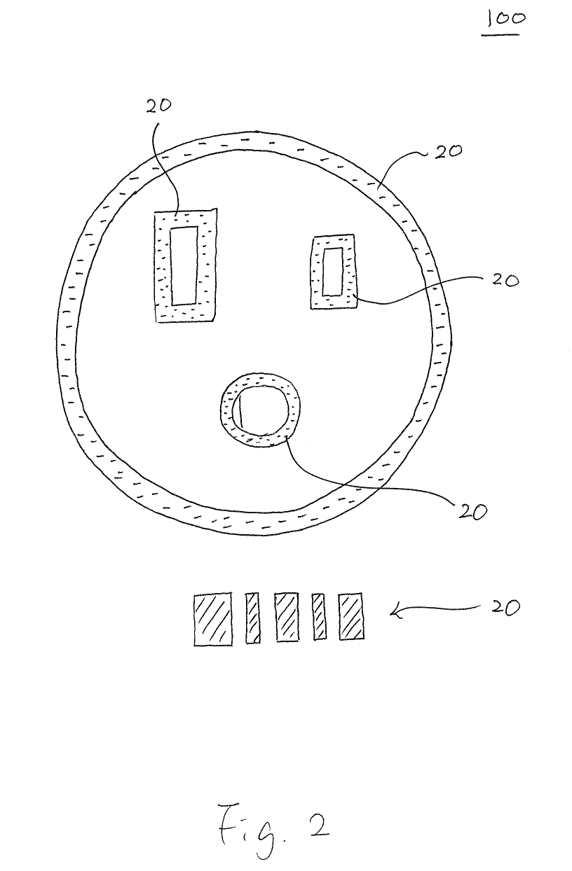

In an aspect of the invention, a night-glow indicator system provides a night-glow power outlet 100 mainly as shown in FIG. 1 and FIG. 2.

The night-glow power outlet 100 has one or more power outlet openings 90, comprising a case 10 and one or more night-glow patches 20.

The case 10 is configured for enclosing and supporting the one or more power outlet openings 90.

The one or more night-glow patches 20 are attached on the case 10 in a vicinity of the one or more power outlet openings 90, and the one or more night-glow patches 20 are configured to indicate information on the one or more power outlet openings 90.

The information comprises rms voltage, peak voltage, rms current, maximum current, and frequency of power, wherein the information further comprises positions of the one or more power outlet openings 90. Some of the one or more night-glow patches 20 are disposed around the one or more power outlet openings 90, and the one or more night-glow patches 20 are arranged to form patterns for indicating the information in the dark.

The one of the night-glow patches 20 may comprise a hole that has a same shape and size of one of the power outlet openings 90, and the night-glow patch 20 may be disposed on the power outlet opening 90 with the hole overlapped on the power outlet opening 90 as shown in FIG. 1 and FIG. 2.

Some of the one or more night-glow patches 20 may be disposed along edges of the case 10.

The patterns may comprise bar-codes, alphanumeric characters, warning symbols, and geometrical shapes.

The night-glow power outlet 100 may further comprise one or more color codes 30, and the one or more color codes 30 may be configured to indicate the information as shown in FIG. 1.

The one or more night-glow patches 20 may comprise the one or more color codes 30 such that the one or more night-glow patches 20 glow in the dark and display colors in the light. That is, one of the night-glow patches 20 and one of the color codes 30 in FIG. 1 can be one body.

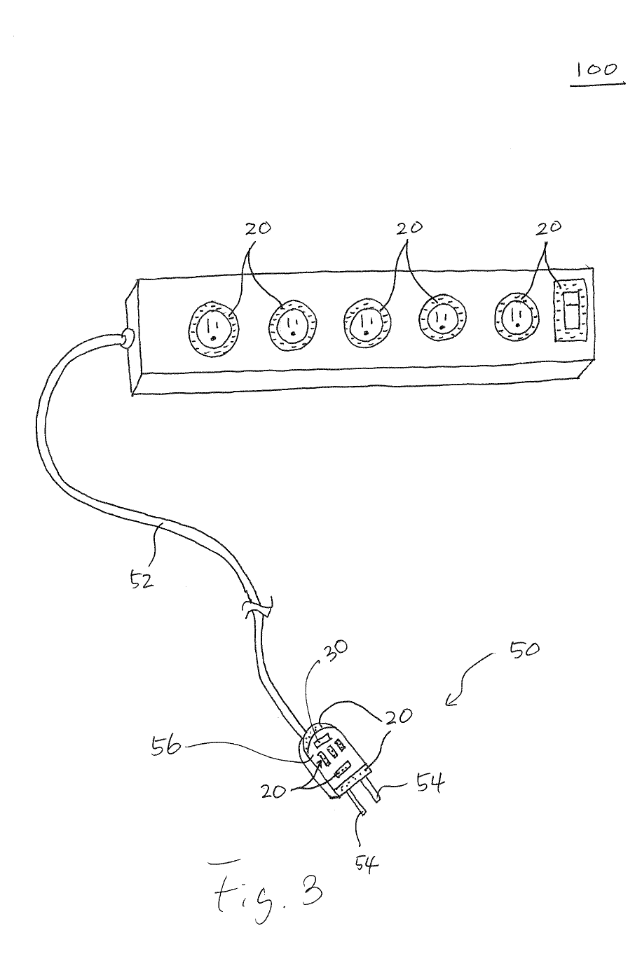

Another aspect of the invention provides a night-glow power cord 50 having an electrical cord 52 and two or more prongs 54 provided at an end of the electrical cord 52 as shown in FIG. 3.

The night-glow power cord 50 comprises a case 56 and one or more night-glow patches 20.

The case 56 is provided between the prongs 54 and the electrical cord 52 and configured for enclosing and supporting the two or more prongs 54.

The one or more night-glow patches 20 are attached on the case 56 in a vicinity of the two or more prongs 54, and the one or more night-glow patches 20 are configured to indicate information on the two or more prongs 54 and an electrical device (not shown) connected to the electrical cord 52.

The information comprises rms voltage, peak voltage, rms current, maximum current, and frequency of power, and the information further comprises positions of the prongs 54. Some of the one or more night-glow patches 20 are disposed around the two or more prongs 54, and the one or more night-glow patches 20 are arranged to form patterns for indicating the information in the dark. Some of the one or more night-glow patches 20 may be disposed along edges of the case 56. The patterns may comprise bar-codes, alphanumeric characters, warning symbols, and geometrical shapes.

The night-glow power cord 50 may further comprise one or more color codes 30, and the one or more color codes 30 may be configured to indicate the information.

The one or more night-glow patches 20 may comprise the one or more color codes 30 such that the one or more night-glow patches 20 glow in the dark and display colors in the light.

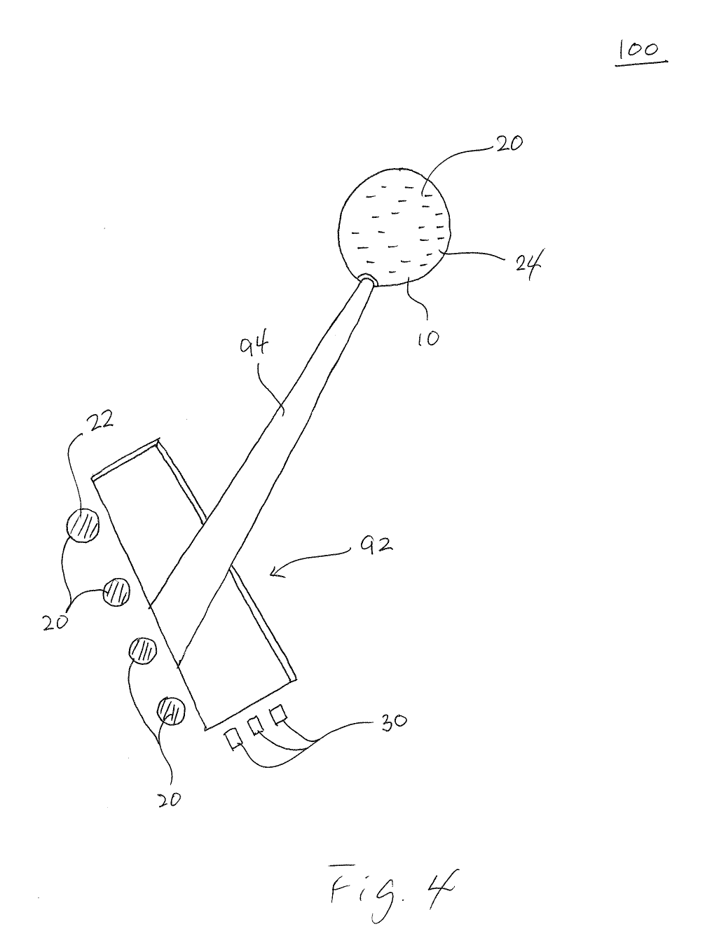

Still another aspect of the invention provides a night-glow color coded device system as shown in FIG. 4.

The night-glow color coded device system 100 comprises an operational device 92, a case 10, a plurality of first night-glow patches 22, a plurality of second night-glow patches 24, and a plurality of color codes 30.

The operational device 92 comprises a plurality of operational parts 94.

The case 10 is configured for enclosing and supporting the plurality of operational parts 94.

The plurality of first night-glow patches 22 are attached on at least one of the operational parts 94.

The plurality of second night-glow patches 24 are attached on the case 10 in a vicinity of the operational parts 94, and the second night-glow patches 24 are configured to indicate information on the operational parts as the first night-glow patches 22.

The plurality of color codes 30 are provided on the case 10, and the color codes 30 are configured to indicate at least one of the information.

The first night-glow patches 22 glow in a fluorescent light different from the second night-glow patches 24, and the information comprises operational status including ON and OFF of the operational device. The one or more night-glow patches 20 are arranged to form patterns for indicating the information in the dark.

The operational device 92 may comprise an electrical device, and the operational parts 94 may comprise power switches, control buttons, and connectors.

The operational device 92 may comprise a mechanical device, and the operational parts 94 may comprise handles, access points, maintenance guide lines, windows, and doors.

The one or more night-glow patches 20 may comprise some of the color codes 30 such that the one or more night-glow patches 20 glow in the dark and display colors in the light. That is, one material may work as a night-glow patch in the dark and as a color codes in the light.

The operational device 92 may comprise an automobile, and the operational parts 94 may comprise handles, knobs, indicators, and output ports of an automobile.

The operational device 92 may comprise a fire extinguisher, and the operational parts 94 may comprise hose, hose connectors, release pins, handles, holders, and direction plates.

A night-glow color-coded indicator system can be adapted to many other objects or devices in which indicating information in the dark is needed. The system helps people to locate the object and to use properly in the dark.

The operational device may comprise a container configured to contain chemical or medical contents, and the operational parts may comprise a lid and an outer surface.

The first night-glow patches may be substantially same as the second night-glow patches, and the night-glow patches may be applied all over the operational device.

Since the invention relates to night-glow indicator systems, the operational device may comprises many devices, a part or an entire body of which needs to be seen in the dark. Such devices may comprise switches, buttons, controls, handles, connectors, docking ports, indicators, containers, knobs, warning signs, instruction plates, etc.

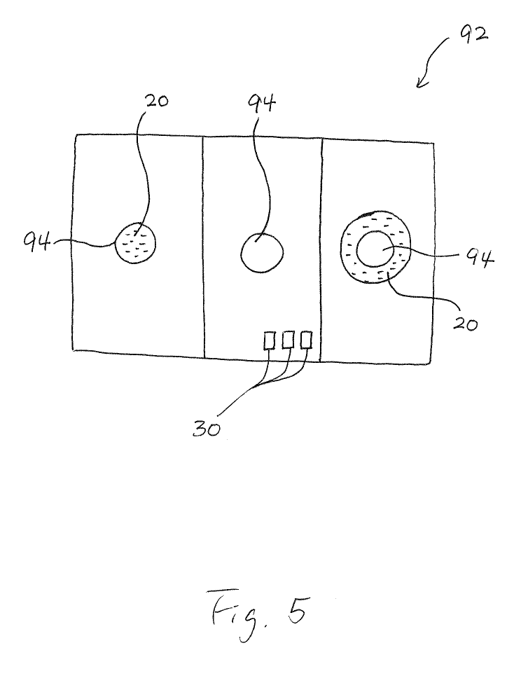

FIGS. 5-9 show night-glow indicator system applied to a plurality of devices according to embodiments of the invention.

FIG. 5 shows three wall push switches 92. In the switch 94 at the left side, the night-glow patch 20 is applied directly on the switch 94 itself. In the switch 94 in the middle, a color code 30 is applied at a right bottom side of the switch 94. In the switch 94 at the right side, the night-glow patch 20 is applied around the switch 94.

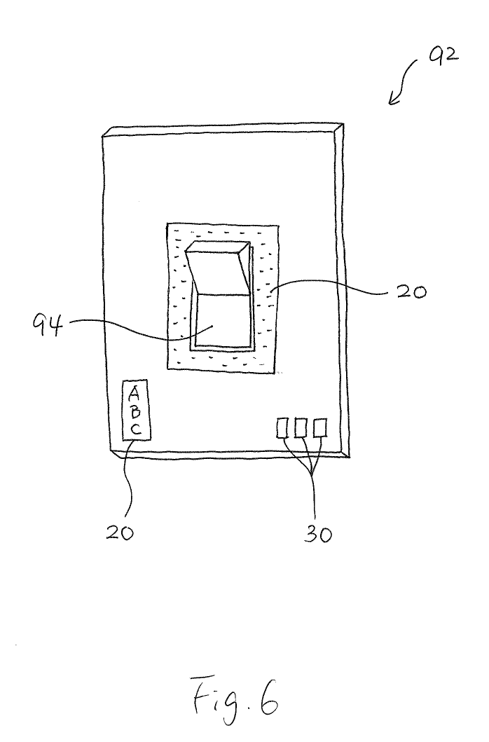

FIG. 6 shows another wall switch device 92. A night-glow patch 20 around the switch 94, a color code 30 at the lower right side of the switch device 92, and a night-glow patch 20 having letters therein are provided in the switch device 92. In certain embodiments, the night-glow patch 20 can be applied all over the switch device, not just around the switch 94.

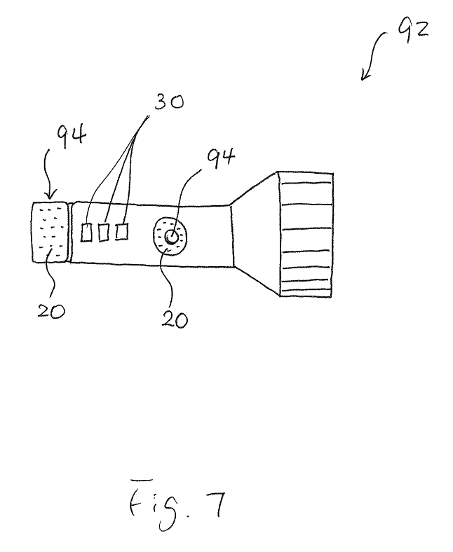

FIG. 7 shows a flashlight 92 having a night-glow patch 20 around the switch 94 and a butt portion, and a color code 30 at a side of the flashlight 92. The butt portion 94 of the flashlight 92 may include a container for battery. It might be challenging to change batteries with such a help from the night-glow patch 20.

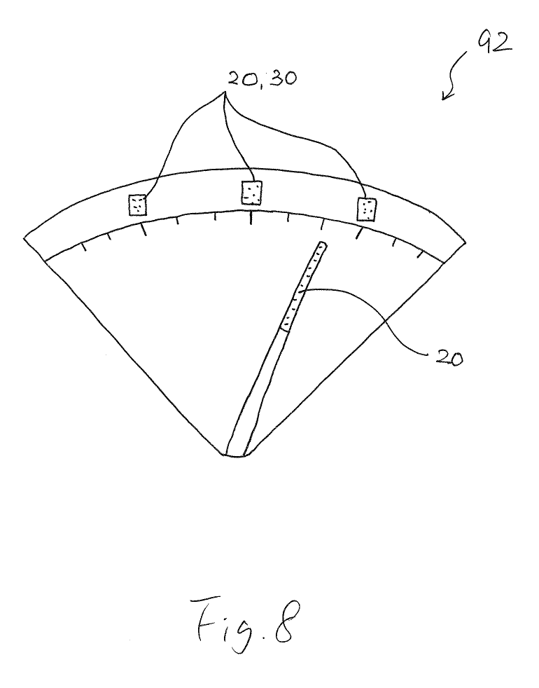

FIG. 8 shows a meter 92. A plurality of night-glow patches 20 and a color code 30 can be applied around the meter 92 such that the needle and the scales are visible even in the dark.

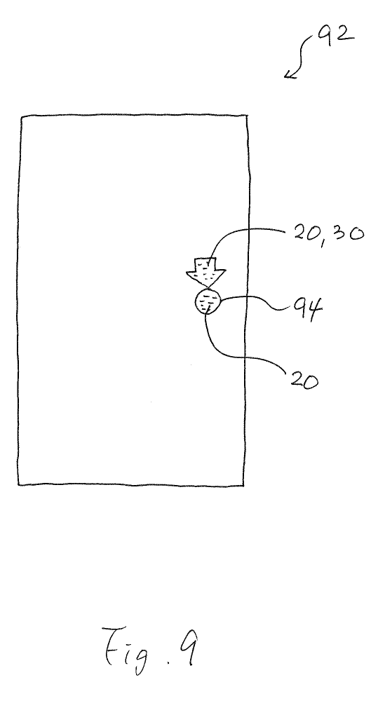

FIG. 9 shows a door 92 having a door handle with a night-glow patch 20. Another night-glow patch 20 can be provided by the door handle to show the location of the door handle or to display a symbol.

While the invention has been shown and described with reference to different embodiments thereof, it will be appreciated by those skilled in the art that variations in form, detail, compositions and operation may be made without departing from the spirit and scope of the invention as defined by the accompanying claims.

What is claimed is:

1. A night-glow power outlet having one or more power outlet openings comprising:
a case configured for enclosing and supporting the one or more power outlet openings, and
one or more night-glow patches attached on the case in a vicinity of the one or more power outlet openings, wherein the one or more night-glow patches are configured to indicate information on the one or more power outlet openings,
wherein the information comprises rms voltage, peak voltage, rms current, maximum current, and frequency of power, wherein the information further comprises positions of the one or more power outlet openings, wherein some of the one or more night-glow patches are disposed around the one or more power outlet openings, and wherein the one or more night-glow patches are arranged to form patterns for indicating the information in the dark.

2. The night-glow power outlet of claim 1, wherein one of the night-glow patches comprises a hole that has a same shape and size of one of the power outlet openings, and wherein the night-glow patch is disposed on the power outlet opening with the hole overlapped on the power outlet opening.

3. The night-glow power outlet of claim 2, wherein some of the one or more night-glow patches are disposed along edges of the case.

4. The night-glow power outlet of claim 1, wherein the patterns comprise bar-codes, alphanumeric characters, warning symbols, and geometrical shapes.

5. The night-glow power outlet of claim 1, further comprising one or more color codes, wherein the one or more color codes are configured to indicate the information.

6. The night-glow power outlet of claim 5, wherein the one or more night-glow patches comprise the one or more color codes such that the one or more night-glow patches glow in the dark and display colors in the light.

7. A night-glow power cord having an electrical cord and two or more prongs provided at an end of the electrical cord comprising:
a case provided between the prongs and the electrical cord and configured for enclosing and supporting the two or more prongs, and
one or more night-glow patches attached on the case in a vicinity of the two or more prongs, wherein the one or more night-glow patches are configured to indicate information on the two or more prongs and an electrical device connected to the electrical cord,
wherein the information comprises rms voltage, peak voltage, rms current, maximum current, and frequency of power, wherein the information further comprises positions of the prongs, wherein some of the one or more night-glow patches are disposed around the two or more prongs, and wherein the one or more night-glow patches are arranged to form patterns for indicating the information in the dark.

8. The night-glow power cord of claim 7, wherein some of the one or more night-glow patches are disposed along edges of the case.

9. The night-glow power cord of claim 7, wherein some of the one or more night-glow patches are disposed along edges of the case.

10. The night-glow power cord of claim 7, wherein the patterns comprise bar-codes, alphanumeric characters, warning symbols, and geometrical shapes.

11. The night-glow power cord of claim 7, further comprising one or more color codes, wherein the one or more color codes are configured to indicate the information.

12. The night-glow power cord of claim 11, wherein the one or more night-glow patches comprise the one or more color codes such that the one or more night-glow patches glow in the dark and display colors in the light.

13. A night-glow color coded device system comprising:
an operational device comprising a plurality of operational parts;
a case configured for enclosing and supporting the plurality of operational parts;
a plurality of first night-glow patches attached on at least one of the operational parts;
a plurality of second night-glow patches attached on the case in a vicinity of the operational parts, wherein the second night-glow patches are configured to indicate information on the operational parts; and
a plurality of color codes provided on the case, wherein the color codes are configured to indicate at least one of the information,
wherein the first night-glow patches glow in a fluorescent light different from the second night-glow patches, wherein the information comprises operational status including ON and OFF of the operational device, and wherein the one or more night-glow patches are arranged to form patterns for indicating the information in the dark.

14. The night-glow color coded device of claim 13, wherein the operational device comprises an electrical device, and wherein the operational parts comprise power switches, control buttons, and connectors.

15. The night-glow color coded device of claim 13, wherein the operational device comprises a mechanical device, and wherein the operational parts comprise handles, access points, maintenance guide lines, windows, and doors.

16. The night-glow color coded device of claim 15, wherein the one or more night-glow patches comprise some of the color codes such that the one or more night-glow patches glow in the dark and display colors in the light.

17. The night-glow color coded device of claim 13, wherein the operational device comprises an automobile, and wherein the operational parts comprise handles, knobs, indicators, and output ports of an automobile.

18. The night-glow color coded device of claim 13, wherein the operational device comprises a fire extinguisher, and wherein the operational parts comprise hose, hose connectors, release pins, handles, holders, and direction plates.

19. The night-glow color coded device of claim 13, wherein the operational device comprises a container configured to contain chemical or medical contents, and wherein the operational parts comprise a lid and an outer surface.

20. The night-glow color coded device of claim 19, wherein the first night-glow patches are substantially same as the second night-glow patches, and wherein the night-glow patches are applied all over the operational device.
